(19) United States
(12) Patent Application Publication
(10) Pub. No.: US 2022/0344203 A1
(43) Pub. Date: Oct. 27, 2022

(54) SEMICONDUCTOR STRUCTURE AND METHOD OF MANUFACTURING SAME

(71) Applicant: CHANGXIN MEMORY TECHNOLOGIES, INC., Hefei City, Anhui Province (CN)

(72) Inventor: Ke MA, Hefei (CN)

(73) Assignee: CHANGXIN MEMORY TECHNOLOGIES, INC., Hefei City, Anhui Province (CN)

(21) Appl. No.: 17/432,527

(22) PCT Filed: Mar. 1, 2021
(86) PCT No.: PCT/CN2021/078508

§ 371 Date: Aug. 20, 2021

(30) Foreign Application Priority Data
Mar. 6, 2020 (CN) 202010152720.5

(51) Int. Cl. H01L 21/768; H01L 21/67; C25D 3/56; C25D 5/18

(52) U.S. Cl. CPC H01L 21/76873; H01L 21/6723; C25D 3/56; C25D 5/18; H01L 21/76877; H01L 21/67103

(57) ABSTRACT

Some of the embodiments of the present application provide a semiconductor structure and a method of manufacturing the same, the method of manufacturing the semiconductor structure comprising: providing a base; performing a first electroplating process to form a first electroplated layer on the base; performing a second electroplating process to form a second electroplated layer on the surface of the first electroplated layer, the current density of the second electroplated layer being greater than the current density of the first electroplated layer.

### CROSS-REFERENCE TO RELATED APPLICATIONS

The present application claims priority to Chinese Patent Application No. 202010152720.5, titled “SEMICONDUCTOR STRUCTURE AND METHOD OF MANUFACTURING SAME” and filed on 6 Mar. 2020, the entire contents of which are incorporated herein by reference.

### TECHNICAL FIELD

Embodiments of the present application relate to the field of semiconductors, in particular to a semiconductor structure and a method of manufacturing the same.

### BACKGROUND

With continuous development of integrated circuit technologies, dimensions of the integrated circuits have a trend of continuous reduction, and a film quality of the integrated circuit has a growing impact on the performance of the integrated circuit.

At present, circuit films are usually formed by an electroplating process. However, parameters of the electroplating process may have certain influence on a defect type and defect quantity of the circuit film. The focused research on film quality improvements is currently oriented to how to control the defect type and defect quantity of a surface film and reduce film surface contamination.

The approaches of producing films in the prior art need to be further improved.

### SUMMARY

Some of the embodiments of the present application provide a semiconductor structure and a method of manufacturing the same, which are beneficial to reducing a defect quantity of the semiconductor device.

In order to solve the problem above, some of the embodiments of the present application provide a method of manufacturing a semiconductor structure, including: providing a base; performing a first electroplating process to form a first electroplated layer on the base; performing a second electroplating process to form a second electroplated layer on a surface of the first electroplated layer, the second electroplated layer having a current density greater than the first electroplated layer.

Further, the step of forming a first electroplated layer on the base includes: immersing the base into an electroplating solution, and performing the first electroplating process before the base is entirely immersed into the electroplating solution; the step of forming a second electroplated layer on a surface of the first electroplated layer includes: performing the second electroplating process after the base is entirely immersed into the electroplating solution.

Further, a current density of the second electroplating process is 141.54 A/m² to 212.31 A/m².

Further, a current density of the first electroplating process is 70.77 A/m² to 141.54 A/m².

Further, after the second electroplated layer is formed, an annealing process is performed on the first electroplated layer and the second electroplated layer.

Further, an annealing temperature of the annealing process is 70° C. to 130° C.

Further, prior to immersing the base into an electroplating solution to perform the first electroplating process, a voltage is applied to the base.

Further, the step of applying a voltage to the base includes applying a voltage of 0˜30V to the base.

Further, the base has a groove provided therein, the first electroplated layer covers a surface of the groove, the groove is filled with the second electroplated layer, and a top surface of the second electroplated layer is higher than that of the base; after the second electroplated layer is formed, a planarization process is performed to remove the second electroplated layer above the top surface of the base.

Correspondingly, some of the embodiments of the present application further provide a semiconductor structure, including: a base; a first electroplated layer located on the base, the first electroplated layer being formed by a first electroplating process; a second electroplated layer located on the surface of the first electroplated layer, the second electroplated layer being formed by a second electroplating process, and a current density of the second electroplating process being greater than that of the first electroplating process.

Further, the base has a groove provided therein, the first electroplated layer covers the surface of the groove, the groove is filled with the second electroplated layer, and the top surface of the second electroplated layer flushes with that of the base.

Further, the semiconductor structure further includes: a barrier layer located on the bottom and side walls of the groove, an electroplating seed layer located on a surface of the barrier layer, and the first electroplated layer is located on a surface of the electroplating seed layer.

The technical solutions according to some of the embodiments of the present application, as compared to the prior art, have the following advantages.

In the technical solutions above, since the first electroplating process has a small current density, a grain stacking rate is low, such that grains can uniformly grow on the surface of the base, thereby eliminating surface defects of the base which may originally exist, and preventing the subsequently formed second electroplated layer from passing and magnifying the surface defects. Meanwhile, since the second electroplating process has a large current density, the grain stacking rate increases, such that the time of growing a single grain is shortened and thus, the grain size is relatively small and the size uniformity among grains is better, which are beneficial to reducing the surface defects of the second electroplated layer.

Moreover, the first electroplating process having a small current density is performed in the course of beginning to immerse the base into the electroplating solution. This is beneficial to preventing a large current from damaging the base, and in turn avoiding the film defects caused by the damaged base.

Furthermore, prior to immersing the base into the electroplating solution to perform the first electroplating process, a voltage is applied to the base, such that the base can act as a cathode at the moment it is immersed into the electroplating solution. Copper ions contained in the electroplating solution move to and deposit on the surface of the cathode. As such, the base can be protected from being corroded by strong acid in the electroplating solution.

### BRIEF DESCRIPTION OF DRAWINGS

The exemplary descriptions of one or more embodiments are made by using the corresponding drawings. These exemplary descriptions are not intended to limit the embodiments. The drawings are not shown to scale unless specifically stated.

FIGS. 1 and 2 are schematic structural diagrams of a cross section of a semiconductor structure;

FIGS. 3 to 10 are schematic structural diagrams of a cross section corresponding to individual steps of a method of manufacturing a semiconductor structure according to an embodiment of the present application; and

FIG. 11 is a diagram of defect quantity variation according to an embodiment of the present application.

### DESCRIPTION OF EMBODIMENTS

At present, an electroplating process having a small current density is used to form a surface film, and after the surface film is formed, an annealing process is performed on the surface film at a high annealing temperature, causing the surface film to have many surface defects.

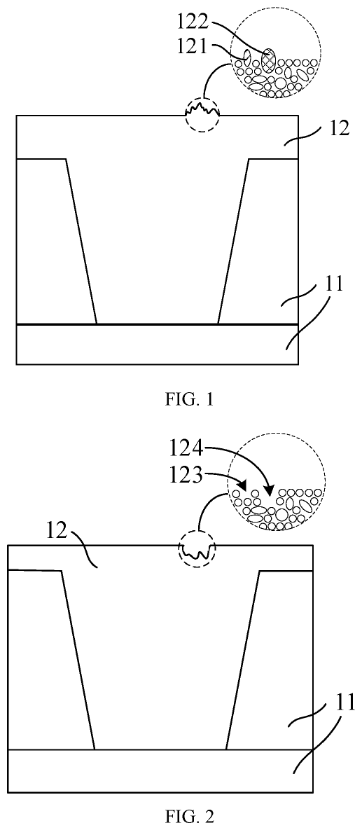

Refer to FIGS. 1 and 2, which are schematic structural diagrams of a cross section of a semiconductor structure.

Referring to FIG. 1, the semiconductor structure includes a base 11 and an electroplated layer 12 located on the base 11. A first grain 121 and a second grain 122, both of which are protruding, are included in the electroplated layer 12. The second grain 122 has a size larger than the first grain 121. The reason for forming the first grain 121 and the second grain 122 is as follows.

During an electroplating process, a grain stacking rate and a grain size are affected by a magnitude of a current density. The magnitude of the current density is in direct proportion to the grain stacking rate, namely, the smaller the current density, the lower the grain stacking rate. Correspondingly, with a lower grain stacking rate, a longer time is required to form an electroplated layer having a constant dimension, i.e., the time of growing grains is longer, thereby enabling the grains to grow to a larger size.

In addition, the grain size is affected by an annealing temperature. A higher annealing temperature would result in a larger degree of under cooling and thus, a higher crystallization rate. That is, in the case where an annealing process is performed on the electroplated layer 12 at a high annealing temperature, the grains in the electroplated layer 12 continue to grow up to a larger size.

Therefore, in the case where a small current density is used to form the electroplated layer 12, or a high annealing temperature is used in the annealing process, it would readily to generate grains having a large size, such that the grains in the electroplated layer 12 have a large grain size and a poor grain size uniformity, which in turn causes part of the grains to protrude, forming a convex defect. A larger grain size would cause a worse convex defect.

The grain size uniformity refers to a size difference among the grains. The smaller the size difference, the better the grain size uniformity. The larger the size difference, the worse the grain size uniformity.

Besides, the applicant of the present application also finds that the surface of the base 11 may have surface defects before the electroplated layer 12 is formed on the surface of the base 11. If a large current density is used in the electroplating process, such defects existing on the surface of the base 11 may be transferred and magnified, and then reflected on the surface of the electroplated layer 12, such that the surface of the second electroplated layer 12 have obvious surface defects.

In the existing process, after the annealing process is performed on the electroplated layer 12, a planarization process is generally performed on the electroplated layer 12 to obtain a flat surface. However, in the case where the grains in the electroplated layer 12 have a large grain size and a poor grain size uniformity, the surface of the electroplated layer 12 subjected to planarization may have a recess defect.

Referring to FIG. 2, the protruding first and second grains have been removed during the planarization process. Accordingly, a first pot hole 123 and a second pot hole 124 appear on the surface of the electroplated layer 12. The size of the pot hole is related to the size of the grain. The second grain is larger than the first grain, and thus, the second pot hole 124 left by the second grain is larger than the first pot hole 123 left by the first grain. That is, the larger the grain size, the worse the recess defect (i.e., pot hole). These pot holes may likely affect subsequent manufacturing processes, and may also be susceptible to contamination of foreign substances, causing a reduced quality of the surface film and affecting the performance of the semiconductor structure.

In order to solve the technical problems above, embodiments of the present application provide a method of manufacturing a semiconductor structure, wherein a first electroplating process having a small current density and a second electroplating process having a large current density are performed sequentially. In the first electroplating process, since a grain stacking rate is low, a first electroplated layer can uniformly grow on the surface of the base, thereby eliminating the surface defects of the base which may originally exist. In the second electroplating process, since the grain stacking rate is high and the time of growing grains is short, the grains in a second electroplated layer are small and have a good grain size uniformity, which in turn causes the second electroplated layer to have less convex defect.

In order to make the objectives, the technical solutions, and the advantages of the embodiments of the present application more clear, the detailed description of the embodiments of the present application is given below in combination with the accompanying drawings. The ordinary skills in the art can understand that many technical details are provided in the embodiments of the present application so as to make the readers better understand the present application. However, even if these technical details are not provided and based on a variety of variations and modifications of the following embodiments, the technical solutions sought for protection in the present application can also be realized.

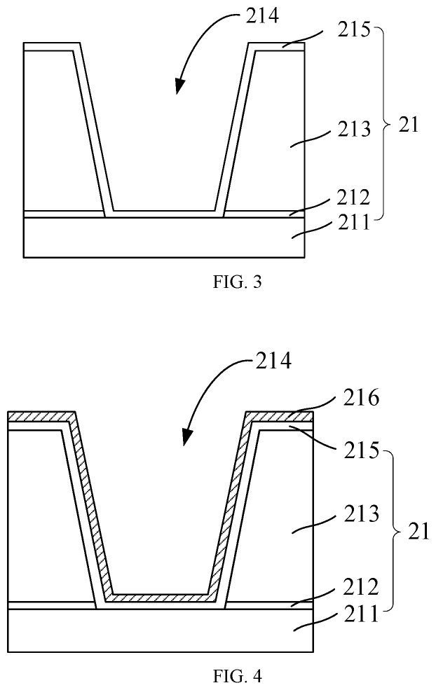

FIGS. 3 to 10 are schematic structural diagrams of a cross section corresponding to individual steps of a method of manufacturing a semiconductor structure according to an embodiment of the present application.

Referring to FIG. 3, in this embodiment, a base 21 includes a substrate 211, an intermediate dielectric layer 213, an etching stop layer 212 located between the substrate and the intermediate dielectric layer, and a groove 214, wherein a metal structure is contained in the substrate 211, the intermediate dielectric layer 213 is an insulating medium, and the etching stop layer 212 is configured to prevent the substrate 211 from being damaged in the course of etching to form the groove 214.

In this embodiment, the base 21 further includes a barrier layer 215 for blocking the permeation of metal of a subsequently formed metal film into the intermediate dielectric layer 213 and even the substrate 211. In addition, in the case where the metal film which is filled in the groove 214 is used to connect the metal structures located in the substrate 211 at different locations, the material of the barrier layer 215 is a conductive material, such that the metal film which is filled in the groove 214 can be electrically connected to the metal structures of the substrate 211.

The material of the metal structure of the substrate 211 includes copper. The material of the intermediate dielectric layer 213 includes silicon oxide or silicon nitride. The material of the etching stop layer 212 includes silicon nitride or silicon carbonitride. The material of the barrier layer 215 includes tantalum.

It should be noted that, in other embodiments, the base has a horizontal surface or a surface of other preset shapes, and the metal material formed on the surface of the base may have functions of communication, electric conduction, or the like.

Referring to FIGS. 4 to 7, a first electroplating process is performed to form a first electroplated layer 22 on the base 21.

Referring to FIG. 4, in order to improve an electroplating efficiency and the quality of the films formed by electroplation, prior to forming the first electroplated layer, the method further includes forming an electroplating seed layer 216 on the base 21. The material of the electroplating seed layer 216 is the same as the metal material to be electroplated later.

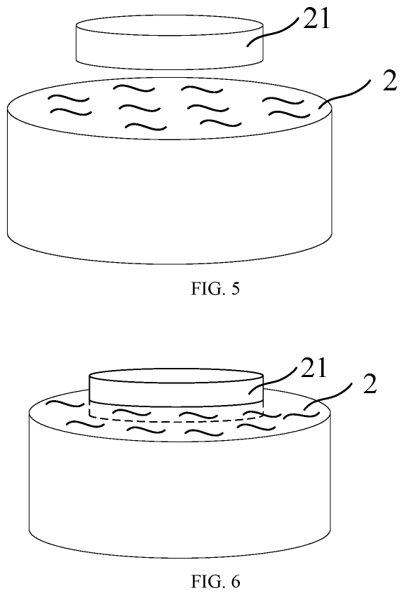

Referring to FIG. 5, a voltage is applied to the base 21 prior to immersing the base 21 into an electroplating solution 2 to perform the first electroplating process.

Prior to immersing the base 21 into the electroplating solution 2, a voltage is applied to the base 21, such that the base 21 can act as a cathode when being immersed into the electroplating solution. As such, the electroplating process begins at the moment the base 21 is immersed into the electroplating solution 2. Cations, such as copper ions, move to the base 21 and deposit on the surface of the base 21, thereby effectively preventing the base 21 from being corroded by the strong acid in the electroplating solution 2, and thus, improving the yield of the semiconductor structure formed subsequently. In this embodiment, prior to immersing the base 21 into the electroplating solution 2, a voltage of 0˜30V, e.g., 5V, 15V, or 25V, is applied to the base 21.

In this embodiment, the first electroplating process having a small current density is first used to perform the electroplation, such that grains can uniformly grow on the surface of the base 21, thereby eliminating the defect of the base 21 which may originally exist on its surface, and preventing the subsequent growth and stack of grains from passing and magnifying this inherent defect.

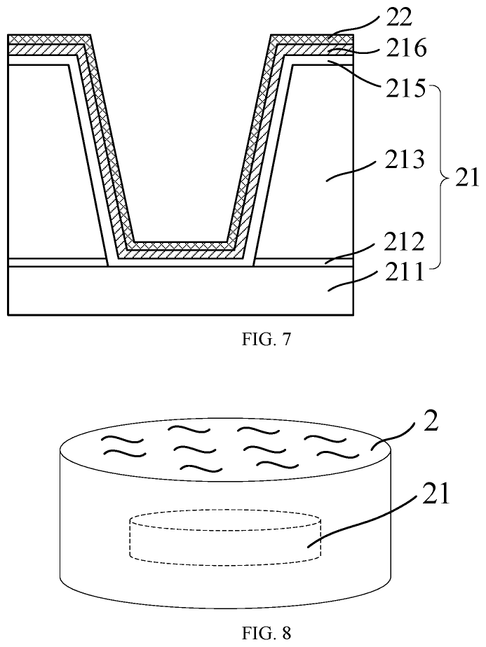

Referring to FIGS. 6 to 7, in this embodiment, the first electroplating process is performed when the base 21 is immersed into the electroplating solution 2 and before the base 21 is entirely immersed into the electroplating solution 2.

Since the current density of the first electroplating process is small, and a contact area between the base 21 and the electroplating solution 2 is smaller in the course of immersing the base 21 into the electroplating solution 2 as compared to the immersion of the entire base 21 into the electroplating solution 2, the current intensity of the surface of the base 21 is small in the course of forming the first electroplated layer 22, which is beneficial to protecting the electroplating seed layer 216 and the first electroplated layer 22 from breakdown damage caused by an overlarge current intensity and thus, avoiding defects of the plated layer, which in turn ensures that the surface of the electroplating seed layer 216 can be covered with the first electroplated layer 22 uniformly.

In this embodiment, the current density of the first electroplating process is 70.77 A/m²˜141.54 A/m², e.g., 90 A/m², 110 A/m², or 130 A/m².

It should be noted that, when the base 21 contacts the electroplating solution 2, the current intensity of the surface of the base 21 is related to not only the current density of the first electroplating process, but also the contact area between the base 21 and the electroplating solution 2. The maximum contact area between the base 21 and the electroplating solution 2 is determined by the dimension of the base 21 (i.e., the area of the electroplating seed layer 216). In the case where the size of the base 21 is overlarge, the electroplating seed layer 216 and the base 21 may experience an overlarge current intensity. In order to avoid such a case, the embodiments of the present application also impose limitation on the maximum current intensity applied in the first electroplating process. Specifically, the current intensity is 5 A to 10 A, for example, 7 A, 8 A, or 9 A.

Since the grain stacking rate is low in the first electroplating process, the speed of immersing the base 21 into the electroplating solution 2 may be adjusted to ensure that the surface of the electroplating seed layer 216 can be covered with the first electroplated layer 22 uniformly.

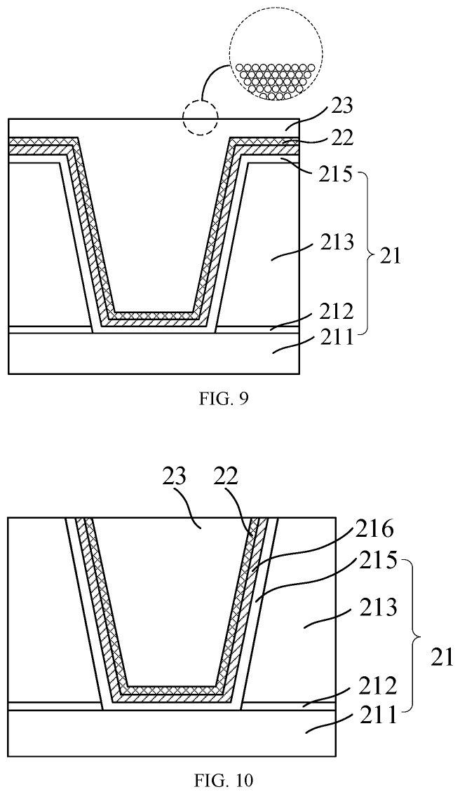

Referring to FIGS. 8 and 9, the second electroplating process is performed to form a second electroplated layer 23 on the surface of the first electroplated layer 22, wherein the second electroplated process has a current density greater than the first electroplated process.

After the base 21 is entirely immersed into the electroplating solution 2, the second electroplating process having a large current density is performed to form the second electroplated layer 23 on the surface of the first electroplated layer 22. Since the second electroplating process has a larger current density, the grain stacking rate is higher and the time of growing a single grain is shorter, such that the grains in the second electroplated layer 23 have a smaller grain size and a better grain size uniformity, i.e., the surface of the second electroplated layer 23 has less convex defects caused by large grain size and poor grain size uniformity.

In this embodiment, the current density of the second electroplating process is 141.54 A/m²˜212.31 A/m², e.g., 150 A/m², 170 A/m², or 190 A/m². By using the current density above, the grain stacking rate increases, such that the time of growing grains in the second electroplated layer 23 is short and thus, all of the grains in the second electroplated layer 23 have a small size, and in turn the second electroplated layer 23 which is formed by the second electroplating process possesses a small grain size and a good grain size uniformity, and in the meantime, the grains in the second electroplated layer 23 have a proper size. Since the volume of the second electroplated layer is constant, the smaller the grain size, the larger the quantity of the grains contained in the second electroplated layer 23. In the case of a large quantity of the grains, the electrons are required to cross more grain boundaries when moving, and thus, a resistance of the second electroplated layer 23 is large. Therefore, in the case where the grains in the second electroplated layer 23 have a proper size, the resistance of the second electroplated layer 23 may be in the preset threshold range, thereby forming a second electroplated layer 23 with less surface defects and good electric conductivity.

In addition, in order to prevent the first electroplated layer 22 and the second electroplated layer 23 from breaking down by a large current intensity, when the second electroplating process is performed, the maximum current intensity is limited between 10 A and 15 A, for example, 12 A, 13 A, or 14 A.

In this embodiment, after the second electroplated layer 23 is formed, an annealing process is performed on the first electroplated layer 22 and the second electroplated layer 23, so as to eliminate a residual stress in the first electroplated layer 22 and the second electroplated layer 23, improving the ductility of the first electroplated layer 22 and the second electroplated layer 23.

The annealing temperature of the annealing process is 70° C. to 130° C., for example, 80° C., 100° C., or 120° C.

As compared to higher temperatures (e.g., 130° C. to 200° C.), performing the annealing process at relatively lower temperatures is beneficial to reducing the rate of growing grains in the first electroplated layer 22 and the second electroplated layer 23, and thus, the grains can only grow to a limited extent in the first electroplated layer 22 and the second electroplated layer 23. This enables the second electroplated layer 23 to possess a good grain size uniformity after undergoing the annealing process, and avoids a rapid growth of grains caused by excessively high annealing temperatures which breaks the grain size suitability and the grain size uniformity of the electroplated layer 23, thereby ensuring that the surface of the second electroplated layer 23 has less surface defects.

In this embodiment, the groove is filled with the second electroplated layer 23, and the top surface of the second electroplated layer 23 is higher than the top surface of the first electroplated layer 22.

Referring to FIG. 10, after the second electroplated layer 23 is formed, the planarization process is performed to remove the second electroplated layer 23 above the top surface of the base 21.

Since the second electroplated layer 23 possesses a small grain size and a good grain size uniformity, and the quantity of large and protruding particles are small, when the planarization process is performed, even if pit holes are generated as the relatively large particles are removed, the generated pit holes are small and the quantity thereof is also small, such that the second electroplated layer 23 still has a smooth surface after the planarization process is performed.

In this embodiment, since the barrier layer 215, the electroplating seed layer 216, and the first electroplated layer 22 are made of metal materials, when the planarization process is performed, the barrier layer 215, the electroplating seed layer 216, the first electroplated layer 22, and the second electroplated layer 23 above the top surface of the base 21 are required to be removed to ensure that the metal structures of the base 21 can be communicated according to preset rules.

It should be further noted that, in other embodiments, if the barrier layer is made of non-metal materials, the barrier layer above the top surface of the intermediate dielectric layer may not be removed.

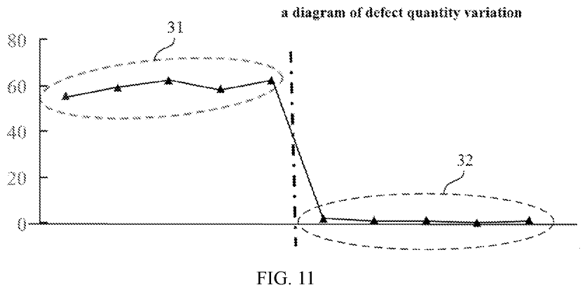

Referring to FIG. 11, given an example that the electroplating density is always 141.54 A/m² to 212.31 A/m² (e.g., 150 A/m², 170 A/m², or 190 A/m²) and the annealing temperature is 130° C. to 200° C. (e.g., 150° C., 170° C., or 190° C.), in the case where the surface of a semiconductor structure is formed by the process described above, a first defect quantity 31 thereof is 50 to 70 per unit area, for example, 55, 60, or 65; in the case where the surface of a semiconductor structure is formed by the process according to this embodiment, a second defect quantity 32 thereof is 0 to 5 per unit area, for example, 1, 2, or 3, which has a significant improvement as compared to the example process.

In this embodiment, the first electroplating process having a small current density and the second electroplating process having a large current density are performed sequentially, such that the inherent defects which originally exist on the base can be eliminated, and the second electroplated layer 23 possesses a good grain size uniformity and a small grain size and thus, has less surface defects, improving the quality of the electroplated film.

Correspondingly, the embodiments of the present application further provide a semiconductor structure.

Referring to FIG. 10, the semiconductor structure includes: a base 21; a first electroplated layer 22 located on the base 21, the first electroplated layer 22 being formed by a first electroplating process; a second electroplated layer 23 located on the surface of the first electroplated layer 22, the second electroplated layer 23 being formed by a second electroplating process, and the current density of the second electroplating process being greater than that of the first electroplating process.

The detailed description of the semiconductor structure according to this embodiment is given below in combination with the accompanying drawings.

In this embodiment, the base 21 includes a substrate 211, an etching stop layer 212, an intermediate dielectric layer 213, and a barrier layer 215, and an electroplating seed layer 216 is provided on the surface of the base 21, the barrier layer 215 being configured to block the permeation of the metal of the electroplating seed layer 216, the first electroplated layer 22, and the second electroplated layer 23 into the intermediate dielectric layer 213 and even the substrate 211, and the electroplating seed layer 216 being configured to improve electroplating efficiency and electroplating quality.

In this embodiment, a groove (not shown) is provided in the base 21, the first electroplated layer 22 covers the surface of the groove, and the groove is filled with the second electroplated layer 23; the top surface of the second electroplated layer 23 flushes with the top surface of the base 21; the second electroplated layer 23 which is filled in the groove serves as wires. In other embodiments, the film which is formed by electroplation performs the function of temperature resistance, anti-corrosion, or the like.

In this embodiment, the first electroplated layer 22, which is formed by the first electroplating process having a small current density, is uniformly overlaid on the surface of the electroplating seed layer 216, in favor for eliminating the surface defects of the area overlaid by the first electroplated layer 22; and the second electroplated layer 23, which is formed by the second electroplating process having a large current density, possesses a good grain size uniformity and a small grain size. As such, the second electroplated layer 23 has less surface defects which include convex defects and recess defects, wherein the convex defect is caused by large and protruding grains, and the recess defect is caused by removing large and protruding grains and thus leaving pit holes.

In this embodiment, the first electroplated layer 22 is uniformly overlaid on the surface of the base 21, and the second electroplated layer 23 which is located on the first electroplated layer 22 possesses a good grain size uniformity and a small grain size, i.e., the second electroplated layer 23 has less surface defects, such that the second electroplated layer 23 has a good film quality.

The ordinary skills in the art can understand that the implementations described above are particular embodiments for implementing the present application. In practical uses, various changes in forms and details may be made to the implementations without departing from the spirit and scope of the present application. Any skills in the art may make their own changes and modifications without departing from the spirit and scope of the present application. Therefore, the protection scope of the present application shall be subject to the protection scope of the claims.

1. A method of manufacturing a semiconductor structure, comprising:
providing a base;
performing a first electroplating process to form a first electroplated layer on the base; and
performing a second electroplating process to form a second electroplated layer on a surface of the first electroplated layer, a current density of the second electroplated process being greater than the current density of the first electroplated process.

2. The method according to claim 1, wherein the forming a first electroplated layer on the base comprises: immersing the base into an electroplating solution, and performing the first electroplating process before the base is entirely immersed into the electroplating solution; and the forming a second electroplated layer on a surface of the first electroplated layer comprises:
performing the second electroplating process after the base is entirely immersed into the electroplating solution.

3. The method according to claim 1, wherein the current density of the second electroplating process is 141.54 A/m² to 212.31 A/m².

4. The method according to claim 3, wherein the current density of the first electroplating process is 70.77 A/m² to 141.54 A/m².

5. The method according to claim 1, wherein an annealing process is performed on the first electroplated layer and the second electroplated layer after the second electroplated layer is formed.

6. The method according to claim 5, wherein an annealing temperature of the annealing process is 70° C. to 130° C.

7. The method according to claim 1, wherein prior to immersing the base into an electroplating solution to perform the first electroplating process, a voltage is applied to the base.

8. The method according to claim 7, wherein the applying a voltage to the base comprises applying a voltage of 0˜30V to the base.

9. The method according to claim 1, wherein the base has a groove provided therein, the first electroplated layer covers a surface of the groove, and the groove is filled with the second electroplated layer, a top surface of the second electroplated layer is higher than the top surface of the base; after the second electroplated layer is formed, a planarization process is performed to remove the second electroplated layer above the top surface of the base.

10. A semiconductor structure, comprising:
a base and a first electroplated layer located on the base, the first electroplated layer being formed by a first electroplating process; and
a second electroplated layer located on the surface of the first electroplated layer, the second electroplated layer being formed by a second electroplating process, and the current density of the second electroplating process being greater than the current density of the first electroplating process.

11. The structure according to claim 10, wherein the base has a groove provided therein, the first electroplated layer covers the surface of the groove, the groove is filled with the second electroplated layer, and the top surface of the second electroplated layer flushes with the top surface of the base.

12. The structure according to claim 11, further comprising:
a barrier layer located on the bottom and side wall of the groove; and an electroplating seed layer located on the surface of the barrier layer, the first electroplated layer being located on the surface of the electroplating seed layer.
